(19) United States
(12) Patent Application Publication
(10) Pub. No.: US 2025/0364227 A1
(43) Pub. Date: Nov. 27, 2025

(54) PLASMA PROCESSING DEVICE AND PLASMA PROCESSING SYSTEM INCLUDING THE SAME

(71) Applicant: Samsung Display Co., Ltd., Yongin-Si (KR)

(72) Inventors: Chang Ho YI, Yongin-si (KR); Sang Gab KIM, Yongin-si (KR); Tae Sung KIM, Yongin-si (KR)

(21) Appl. No.: 19/006,284

(22) Filed: Dec. 31, 2024

(30) Foreign Application Priority Data
May 24, 2024 (KR) 10-2024-0067946

(51) Int. Cl. H01J 37/32

(52) U.S. Cl. CPC H01J 37/32651; H01J 37/32119; H01J 37/32522

(57) ABSTRACT

A plasma processing device according to an embodiment includes a chamber in which plasma process is performed, a radio frequency antenna connected to a radio frequency power source, a dielectric window disposed between the radio frequency antenna and the chamber, a first Faraday shield disposed on the chamber and including first portions and first openings, and a second Faraday shield disposed inside the chamber and including second portions and second openings. The first openings and the second openings may be alternately arranged in a staggered manner along a perpendicular direction.

### CROSS-REFERENCE TO RELATED APPLICATION

This application claims priority to and the benefit of Korean Patent Application No. 10-2024-0067946 filed on May 24, 2024, in the Korean Intellectual Property Office under 35 U.S.C. § 119, the entire contents of which are incorporated herein by reference.

### BACKGROUND

### 1. Field

The present disclosure relates to a plasma processing device and a plasma processing system including the same.

### 2. Description of the Related Art

A display device includes a liquid crystal display (LCD), a plasma display panel (PDP), an organic light emitting diode (OLED) device, a field emission display (FED), and an electrophoretic display device.

The display device includes signal lines and layers such as a light emitting layer, and some stacking layers including a metal layer may be etched to form the signal lines. As the metal layer, copper is typically used due to its low resistance. However, a by-product of copper after reaction has low volatility, and may cause an issue of the by-produce of copper attaching onto an interior of a chamber of an etching device. When the by-product forms a film on an RF window and a Faraday shield, a power transfer efficiency into a plasma treatment space may be reduced due to eddy currents. Therefore, it is necessary to periodically clean the interior of the chamber.

### SUMMARY

The present disclosure provides a plasma processing device which prevents the weakening of an induced electric field caused by the formation of the eddy currents through an arrangement of Faraday shields, and a plasma processing system including the same.

According to an embodiment of the present disclosure, plasma processing device includes a chamber in which plasma process is performed, a radio-frequency antenna connected to a radio-frequency power source, a dielectric window disposed between the radio-frequency antenna and the chamber, a first Faraday shield disposed on the chamber and including first portions and first openings, and a second Faraday shield disposed inside the chamber and including second portions and second openings. The first openings and the second openings may be alternately arranged in a staggered manner along a perpendicular direction to an upper surface of the chamber.

The first portions may radially extend outward from a center of the first Faraday shield and may be connected to a first edge, and the second portions may radially extend outward from a center of the second Faraday shield and may be connected to a second edge.

The first portions and the first openings may be alternately arranged in a plan view, and the second portions and the second openings may be alternately arranged in the plan view.

The first portions may at least partly overlap the second openings in the perpendicular direction, and the second portions may at least partly overlap the first openings in the perpendicular direction.

The first Faraday shield may be spaced apart from the second Faraday shield in the perpendicular direction.

The first Faraday shield may be separated from the chamber by an insulating layer or may be coated with an insulating film.

The first Faraday shield may be integrally formed with the dielectric window.

The first Faraday shield may be disposed between the radio frequency antenna and the dielectric window.

The plasma processing device may further include a support member disposed inside the chamber. The support member may attach the second Faraday shield to the upper surface of the chamber or an interior wall of the chamber.

The first Faraday shield and the second Faraday shield may be made of a non-magnetic metal.

A surface of the second Faraday shield may be coated with at least one of Al₂O₃ and Y₂O₃.

The first Faraday shield and the second Faraday shield may have quadrangular shapes.

According to an embodiment of the present disclosure, a plasma processing system includes a plasma processing device including a chamber in which plasma process is performed, a radio frequency antenna connected to a radio frequency power source, a dielectric window disposed between the radio frequency antenna and the chamber, a first Faraday shield disposed on the chamber and including first portions and first openings, and a second Faraday shield disposed inside the chamber and including second portions and second openings, a power supply disposed outside the chamber and connected to the second Faraday shield, and a cooling fluid supplying portion connected to a cooling path of the second Faraday shield. The first openings and the second openings are alternately arranged in a staggered manner.

The power supply may supply at least one of DC voltage, AC current, or RF electric power to the second Faraday shield.

The cooling fluid supplying portion may supply a liquefied or gaseous fluid to an inlet of the cooling path to adjust a temperature of the second Faraday shield.

The first Faraday shield may include first portions radially extending outward from a center and connected to a first edge, and the second Faraday shield may include second portions radially extending outward from a center and connected to a second edge.

The first portions and the first openings may be alternately arranged in a plan view, and the second portions and the second openings may be alternately arranged in the plan view.

The first portions may at least partly overlap the second openings in a perpendicular direction to an upper surface of the chamber, and the second portions may at least partly overlap the first openings in the perpendicular direction.

The first Faraday shield may be integrally formed with the dielectric window.

The first Faraday shield may be disposed between the radio frequency antenna and the dielectric window.

According to an embodiment, weakening of the induced electric field caused by the formation of the eddy current may be prevented by alternately arranging the openings included in each of the Faraday shields in a staggered manner.

### BRIEF DESCRIPTION OF THE DRAWINGS

FIG. 1 shows a plasma processing system according to an embodiment.

FIG. 2 shows a plan view of a first Faraday shield of FIG. 1 according to an embodiment.

FIG. 3 shows a plan view of a second Faraday shield of FIG. 1 according to an embodiment.

FIG. 4 shows structures of a first Faraday shield and a second Faraday shield in a plasma processing device according to an embodiment.

FIG. 5 shows a variation of structures of a first Faraday shield and a second Faraday shield shown in FIG. 4.

FIG. 6 shows structures of a first Faraday shield and a second Faraday shield in a plasma processing device according to an embodiment.

FIG. 7 shows a variation of structures of a first Faraday shield and a second Faraday shield shown in FIG. 6.

FIG. 8 shows an attachment of by-products to a first Faraday shield and a second Faraday shield in a plasma processing device according to an embodiment.

FIG. 9 shows a variation of the attachment of by-products to a first Faraday shield and a second Faraday shield shown in FIG. 8.

FIG. 10 shows an attachment of by-products to a first Faraday shield and a second Faraday shield in a plasma processing device according to an embodiment.

FIG. 11 shows a variation of the attachment of by-products to a first Faraday shield and a second Faraday shield shown in FIG. 10.

### DETAILED DESCRIPTION

The present disclosure will be described more fully hereinafter with reference to the accompanying drawings, in which embodiments of the disclosure are shown. As those skilled in the art may realize, the described embodiments may be modified in various different ways, all of which, however, are not departing from the spirit or scope of the present disclosure.

The drawings and description are regarded as illustrative in nature and not restrictive, and like reference numerals refer to like elements throughout the specification.

Furthermore, the accompanying drawings are intended only to facilitate understanding of the embodiments disclosed herein, and it is to be understood that the technical ideas disclosed herein are not limited by the accompanying drawings and include all modifications, equivalents, and substitutions without departing from the scope and spirit of the present disclosure.

The size and thickness of each configuration shown in the drawings are arbitrarily illustrated for better understanding and ease of description of the present disclosure, but the present disclosure is not limited thereto. The thickness of layers, films, panels, regions, etc., are enlarged for clarity. For ease of description, the thicknesses of some layers and areas are exaggerated.

It should be understood that when an element such as a layer, film, region, or substrate is referred to as being “on” another element, it can be directly on the other element, or intervening elements may also be present. In contrast, when an element is referred to as being “directly on” another element, there are no intervening elements present therebetween. It should be understood that when an element such as a layer, film, region, or substrate is referred to as being “on” another element, it may be directly on the other element or indirectly on the other element with intervening elements interposed therebetween.

Unless explicitly described to the contrary, the word “comprise”, and variations such as “comprises” or “comprising”, should be understood to imply the inclusion of stated elements but not the exclusion of any other elements.

The phrase “in a plan view” means viewing an object from the top, and the phrase “in a cross-sectional view” means viewing a cross-section of the object, in which the object is vertically cut, from the side.

Also, when it is stated that a part is “attached” (or “in contact with,” “coupled)” to another part, the part may be “directly attached” to the other element, may be “attached” to the other part through a third part, or may be attached to the other part physically or electrically.

An embodiment of the present disclosure will now be described in detail with reference to accompanying drawings.

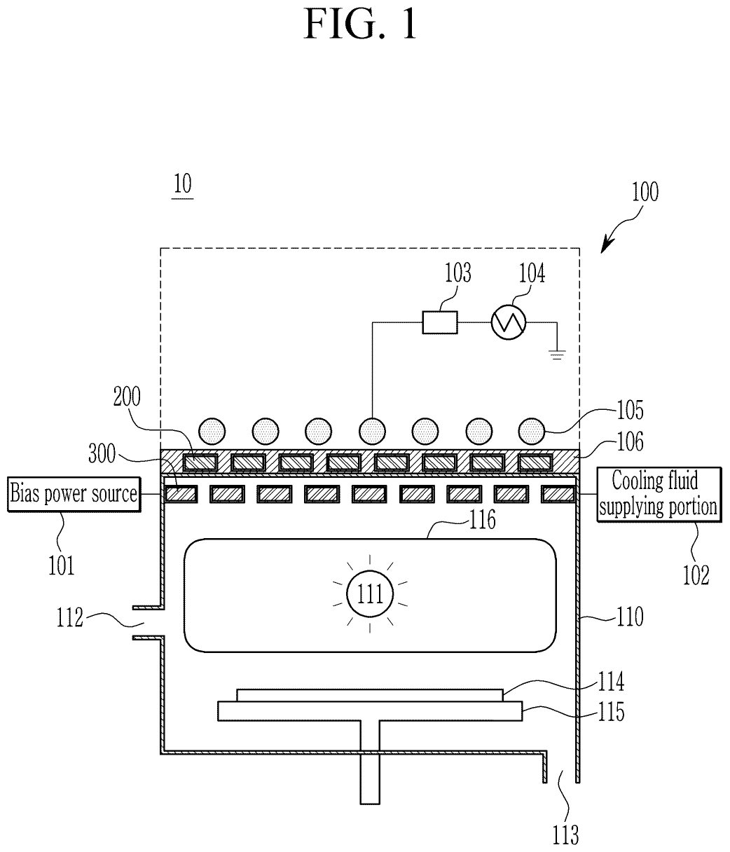

FIG. 1 shows a plasma processing system according to an embodiment.

Referring to FIG. 1, the plasma processing system 10 may include a plasma processing device 100 having a plasma processing chamber 116, a bias power source 101 for supplying at least one of power, current, and electric power, and a cooling fluid supplying portion 102 for supplying fluid to an inlet of a cooling path (not shown). The present embodiment discloses the plasma processing device using an inductively coupled plasma (ICP) generated by an inductive coupling (IC) method. However, the present embodiment is not limited thereto, and it may also be applied to the plasma processing devices using plasma generated by various other methods. In various embodiments, the plasma processing system 10 may omit at least one of the above-described components or may additionally include other components.

According to an embodiment, the plasma processing device 100 may include a first Faraday shield 200, a second Faraday shield 300, a matcher 103, a radio frequency power source 104, a radio frequency antenna 105 connected to the radio frequency power source 104, a chamber 110, and a dielectric window 106 arranged between the radio frequency antenna 105 and the chamber 110. In various embodiments, the plasma processing device 100 may omit at least one of the above-described components or may additionally include other components.

Each of the first Faraday shield 200 and the second Faraday shield 300 may work as physical shields for protecting at least a portion of an inside of the chamber 110 from undesired redeposition of the material. Particularly, the first Faraday shield 200 and the second Faraday shield 300 may work as sputter shields protecting against the redeposition of the conductive material. First portions 211 of the first Faraday shield 200 and second portions 311 of the second Faraday shield 300 may be formed to have sufficient lengths and may shield electric fields generated by the radio frequency antenna 105. The first Faraday shield 200 and the second Faraday shield 300 may be grounded through the chamber 110 or may be connected to an additional ground line.

According to an embodiment, the first Faraday shield 200 may be arranged on the chamber 110. According to an embodiment, the first Faraday shield 200 may be integrally formed with the dielectric window 106. According to an embodiment, the first Faraday shield 200 may be integrally formed with the dielectric window 106 and may form an upper surface of the chamber 110. According to an embodiment, the first Faraday shield 200 may be surrounded by the dielectric window 106.

According to an embodiment, the first Faraday shield 200 may be arranged between the radio frequency antenna 105 and the dielectric window 106. For example, the first Faraday shield 200 may contact an upper surface of the dielectric window 106 between the radio frequency antenna 105 and the dielectric window 106.

According to an embodiment, the first Faraday shield 200 may be provided as a metallic material to shield the electric field. For example, the first Faraday shield 200 may be made of a non-magnetic metal. For example, the first Faraday shield 200 may be made of copper.

According to an embodiment, the first Faraday shield 200 may be separated from the chamber 110 by the insulating layer (e.g., the dielectric window 106). According to an embodiment, a surface of the first Faraday shield 200 may be coated with an insulating film.

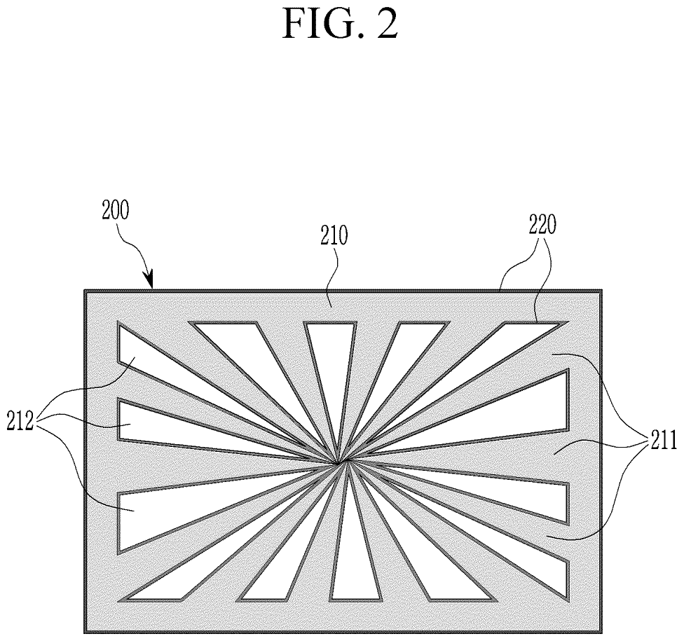

According to an embodiment, the first Faraday shield 200 may have a shape similar to the substrate 114. For example, the first Faraday shield 200 may have a substantially quadrangular planar shape when seen in a direction perpendicular to the upper surface of the first Faraday shield 200. However, without being limited thereto, the first Faraday shield 200 may have various planar shapes according to the planar structures of the chamber 110, the plasma processing chamber 116, the substrate support member 115, and the substrate 114. The shape of the first Faraday shield 200 will be described in detail with reference to FIG. 2.

According to an embodiment, the second Faraday shield 300 may be arranged inside the chamber 110. In detail, the second Faraday shield 300 may be secured by a support member (not shown) and may be exposed to the chamber 110. In further detail, the second Faraday shield 300 may be secured to an upper portion (e.g., an internal surface of an upper portion of the chamber 110) of the chamber 110 or an interior wall of the chamber 110 by a support member (not shown).

According to an embodiment, the second Faraday shield 300 may be vertically spaced apart from the first Faraday shield 200 at a predetermined distance. In detail, the second Faraday shield 300 may be vertically spaced apart from the first Faraday shield 200 at a predetermined distance, and each of the second Faraday shield 30 may be arranged in parallel with each other.

According to an embodiment, a gap between the first Faraday shield 200 and the second Faraday shield 300 when the first Faraday shield 200 is integrally formed with the dielectric window 106 may be less than a gap between the first Faraday shield 200 and the second Faraday shield 300 when the first Faraday shield 200 is arranged between the radio frequency antenna 105 and the dielectric window 106.

According to an embodiment, the second Faraday shield 300 may be provided as a metallic material to shield the electric field. For example, the second Faraday shield 300 may be provided as a non-magnetic metallic material. For example, the second Faraday shield 300 may be made of copper. According to an embodiment, the surface of the second Faraday shield 300 may be coated with at least one of Al₂O₃ and Y₂O₃.

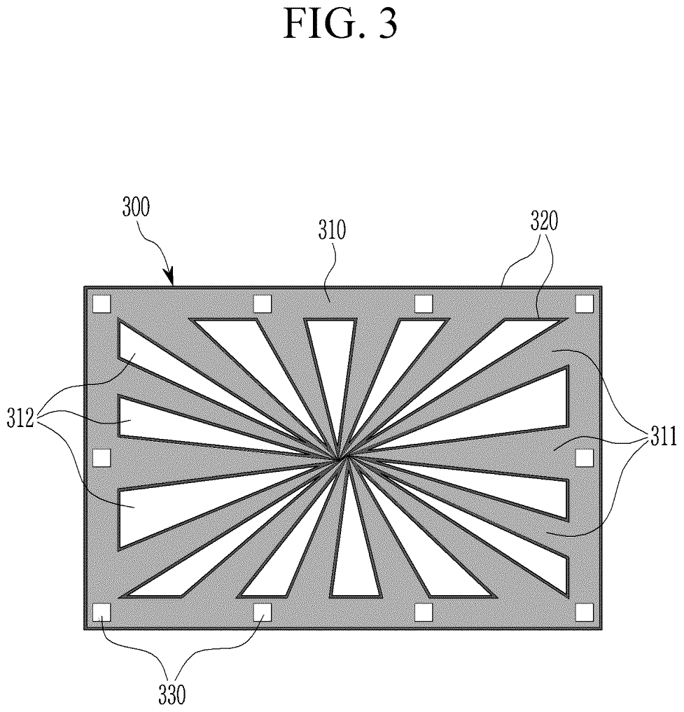

According to an embodiment, the second Faraday shield 300 may have a shape similar to the substrate 114. For example, the second Faraday shield 300 may have a substantially quadrangular planar shape when seen in the direction perpendicular to the upper surface of the second Faraday shield 300. However, without being limited thereto, the second Faraday shield 300 may have various planar shapes according to the planar structures of the chamber 110, the plasma processing chamber 116, the substrate support member 115, and the substrate 114. The shape of the second Faraday shield 300 will be described in detail with reference to FIG. 3.

According to an embodiment, the radio frequency antenna 105 may be arranged on the chamber 110. The radio frequency antenna 105 may be arranged on the chamber 110 with the dielectric window 106 therebetween. According to an embodiment, the radio frequency antenna 105 may be an inductively coupling plasma antenna and may be made of a conductor spirally wound in a clockwise direction or a counterclockwise direction. That is, the radio frequency antenna 105 may include a coil spirally wound in the clockwise direction or the counterclockwise direction.

According to an embodiment, the radio frequency antenna 105 may have a shape that is symmetrical about a center point on a plane. According to an embodiment, the radio frequency antenna 105 may have a symmetrical structure to form an induced electric field with constant intensity in an internal space of the plasma processing chamber 116.

According to an embodiment, the radio frequency antenna 105 may have a quadrangular spiral coil planar shape when seen in the direction perpendicular to the upper surface of the chamber 110. However, without being limited thereto, the radio frequency antenna 105 may have various planar shapes according to the planar structures of the chamber 110, the plasma processing chamber 116, the substrate support member 115, and the substrate 114.

The radio frequency antenna 105 may have curved portions and may have a spirally wound form. According to an embodiment, the curved portions of the radio frequency antenna 105 may be curved at a predetermined angle (e.g., 90 degrees). For example, the radio frequency antenna 105 may be curved in a corner region at a predetermined angle. However, without being limited thereto, the radio frequency antenna 105 may be curved in a round shape with a predetermined radius.

The spiral coils constituting the radio frequency antenna 105 may be formed in parallel to each other with predetermined gaps therebetween to maintain appropriate gaps in which there is no current interference.

According to an embodiment, the radio frequency antenna 105 may be connected to the radio frequency power source 104 through the matcher 103. The matcher 103 may be disposed between the radio frequency antenna 105 and the radio frequency power source 104 and match an impedance of the radio frequency antenna 105.

In detail, one end of the radio frequency antenna 105 arranged in a center of the spiral of the radio frequency antenna 105 may be connected to the radio frequency power source 104. Another end of the radio frequency antenna 105 may be grounded.

According to an embodiment, the radio frequency antenna 105 may be connected to the radio frequency power source 104 which supplies radio frequency (RF) power. In detail, one end of the radio frequency antenna 105 arranged in the center of the spiral of the radio frequency antenna 105 may be connected to the radio frequency power source 104. According to an embodiment, the RF power of the radio frequency power source 104 may be distributed to the radio frequency antenna 105.

According to an embodiment, the matcher 103 may be installed between the radio frequency antenna 105 and the radio frequency power source 104. The matcher 103 may be disposed between the radio frequency antenna 105 and the radio frequency power source 104 for impedance matching of the radio frequency antenna 105.

According to an embodiment, the dielectric window 106 may be arranged between the radio frequency antenna 105 and the chamber 110. The dielectric window 106 may reduce capacitive coupling between the radio frequency antenna 105 and the plasma 111 to facilitate transmission of the energy from the radio frequency power source 104 to the plasma 111 through inductive coupling.

According to an embodiment, the interior of the chamber 110 may include the second Faraday shield 300, a support member (not shown) for securing the second Faraday shield 300 to the interior of the chamber 110, the plasma processing chamber 116 where plasma 111 processing is performed, and the substrate support member 115 for placing the substrate 114 or the like.

For example, the substrate support member 115 may use an electrostatic chuck (ESC) that holds and supports the substrate 114 through electrostatic force. The substrate support member 115 may use a mechanical clamping method to fix the substrate 114, or a vacuum chuck that holds and supports the substrate through vacuum pressure.

According to an embodiment, the chamber 110 may include a gas inlet 112 and a fluid outlet 113. The chamber 110 may include the gas inlet 112 for supplying reaction gas to the plasma processing chamber 116 and the fluid outlet 113 for maintaining the plasma processing chamber 116 of the chamber 110 in a vacuum and discharging the reaction gas when the reaction ends.

According to an embodiment, an etching process using plasma may be performed in the chamber 110. Inside the chamber 110, etching gas supplied through the gas inlet 112 may be transformed into a plasma state by radio frequency power, allowing the etching process of the substrate 114 to proceed.

According to an embodiment, the bias power source 101 may be connected to the second Faraday shield 300. According to an embodiment, the bias power source 101 may apply at least one of a voltage, current, and electric power to the second Faraday shield 300 during a process. According to an embodiment, the bias power source 101 may apply at least one of the voltage, current and electric power to the second Faraday shield 300 while cleaning plasma between processes.

As described above, regarding the plasma processing system 10 according to the present disclosure, the bias power source 101 may apply electric power during the plasma cleaning between processes, thereby allowing an in-situ cleaning of the dielectric window 106 and the second Faraday shield 300. The forms of the electric power may include at least one of DC electric power, AC electric power, and RF electric power.

According to an embodiment, the cooling fluid supplying portion 102 may be connected to the second Faraday shield 300. According to an embodiment, a cooling path (not shown) may be formed on the second Faraday shield 300. For example, the cooling path (not shown) may be provided inside the second Faraday shield 300.

According to an embodiment, the cooling fluid supplying portion 102 may supply a liquefied or gaseous fluid to an inlet of the cooling path (not shown) to adjust a temperature of the second Faraday shield 300. In detail, the cooling fluid supplying portion 102 may supply a high-temperature fluid to the inlet of the cooling path and may maintain the second Faraday shield 300 in a high-temperature state. As described above, in the plasma processing system 10 according to the present disclosure, reattachment of an etching by-product may be controlled or suppressed by maintaining the second Faraday shield 300 in a high-temperature state.

FIG. 2 shows a plan view of a first Faraday shield of FIG. 1 according to an embodiment.

Referring to FIG. 2, the first Faraday shield 200 may have a shape that is symmetrical with respect to the center point in a plan view. According to an embodiment, the first Faraday shield 200 may have a substantially quadrangular planar shape when seen in a direction perpendicular to the upper surface of the chamber 110. For example, the first Faraday shield 200 may have a rectangular planar shape. A length of a horizontal side and a length of a vertical side of the first Faraday shield 200 may be different from each other. That is, the first Faraday shield 200 may have a long side and a short side. However, without being limited thereto, the first Faraday shield 200 may have various planar shapes according to the planar structures of the chamber 110, the plasma processing chamber 116, the substrate support member 115, and the substrate 114.

According to an embodiment, the first Faraday shield 200 may include the first portions 211 and the first openings 212. According to an embodiment, each of the first portions 211 may have a radial pattern coming from the center of the first Faraday shield 200. According to an embodiment, the quadrangular first Faraday shield 200 may include a first edge 210. The first edge 210 may correspond to an outer region of the first Faraday shield 200.

According to an embodiment, the first portions 211 may radially extend to an outside from the center of the first Faraday shield 200 and may be connected to the first edge 210. For example, the first portions 211 may be integrally formed with the first edge 210.

According to an embodiment, the first portions 211 may be spaced apart from each other. According to an embodiment, a plurality of the first openings 212 may be formed between the plurality of the first portions 211. That is, the first openings 212 and the first portions 211 may be alternately arranged (or formed) along an extension direction of the first edge 210. The first openings 212 may be spaced apart from each other.

According to an embodiment, the gap between the two adjacent first portions 211 may gradually increase as it moves outward from the center of the first Faraday shield 200.

According to an embodiment, the gap between one pair of adjacent first portions 211 may be the same as the gap between another pair of adjacent first portions 211, but it is not limited to this and may also be different from each other.

According to an embodiment, the first Faraday shield 200 may include a first insulating film 220 coated on at least a portion of the surface. That is, the surface of the first Faraday shield 200 may be coated with the first insulating film 220.

According to an embodiment, the surface of the first Faraday shield 200 may be coated with the first insulating film 220 when arranged between the radio frequency antenna (e.g., the radio frequency antenna 105 of FIG. 1) and the dielectric window (e.g., the dielectric window 106 of FIG. 1). According to an embodiment, when the first Faraday shield 200 is integrally formed with the dielectric window 106, the first Faraday shield 200 may not be coated with the first insulating film 220 because the dielectric window 106 may serve as the insulating film. However, the present disclosure is not limited thereto, and the first Faraday shield 200 may be coated with the first insulating film 220.

FIG. 3 shows a plan view of a second Faraday shield of FIG. 1 according to an embodiment.

Referring to FIG. 3, the second Faraday shield 300 according to an embodiment may have a shape that is symmetrical with respect to the center point in a plan view. According to an embodiment, the second Faraday shield 300 may have a substantially quadrangular planar shape when seen in a perpendicular direction to the upper surface of the chamber 110. For example, the second Faraday shield 300 may have a rectangular planar shape. A length of a horizontal side and a length of a vertical side of the second Faraday shield 300 may be different from each other. That is, the second Faraday shield 300 may have a long side and a short side. However, without being limited thereto, the second Faraday shield 300 may have various planar shapes according to the planar structures of the chamber 110, the plasma processing chamber 116, the substrate support member 115, and the substrate 114.

According to an embodiment, the second Faraday shield 300 may include second portions 311 and second openings 312. According to an embodiment, each of the second portions 311 may have a radial pattern coming from the center of the second Faraday shield 300. According to an embodiment, the quadrangular-shaped second Faraday shield 300 may include a second edge 310. The second edge 310 may correspond to an outer region of the second Faraday shield 300.

According to an embodiment, the second portions 311 may radially extend outward from the center of the second Faraday shield 300 and may be connected to the second edge 310. For example, the second portions 311 may be integrally formed with the second edge 310.

According to an embodiment, the second portions 311 may be spaced apart from each other. According to an embodiment, a plurality of the second openings 312 may be formed between a plurality of the second portions 311. That is, the second openings 312 and the second portions 311 may be alternately arranged (or formed) along an extending direction of the second edge 310. The second openings 312 may be spaced apart from each other.

According to an embodiment, the gap between the two adjacent second portions 311 may gradually increase as it moves outward from the center of the second Faraday shield 300.

According to an embodiment, the gap between one pair of adjacent second portions 311 may be the same as the gap between another pair of adjacent second portions 311, but it is not limited to this and may also be different from each other.

According to an embodiment, the second Faraday shield 300 may include the second insulating film 320 coated on at least a portion of the surface. That is, the surface of the second Faraday shield 300 may be coated with the second insulating film 320. For example, a material of the second insulating film 320 may include at least one of Al₂O₃ and Y₂O₃.

According to an embodiment, the second Faraday shield 300 may include at least one support region 330 attached to a support member (not shown). For example, the support region 330 may be formed on the second edge 310. When the second Faraday shield 300 has a rectangular planar shape, the number of the support regions 330 formed on the long side of the second edge 310 may be greater than the number of the support regions 330 formed on the short side of the second edge 310, but the present disclosure is not limited thereto.

According to an embodiment, the second Faraday shield 300 may be attached to an upper portion of the chamber 110 or an interior wall of the chamber 110 by a support member (not shown) and may be exposed inside the chamber 110.

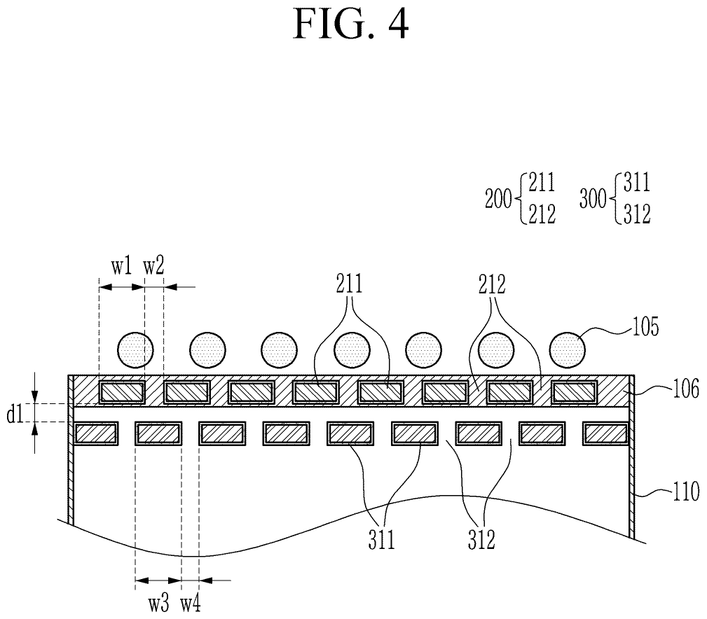

The plasma processing device to be described with reference to FIG. 4 to FIG. 11 mostly corresponds to the plasma processing device according to an embodiment shown in FIG. 1, so the repeated content may be summarized or omitted. The same components as the above-described embodiment may use the same reference numerals.

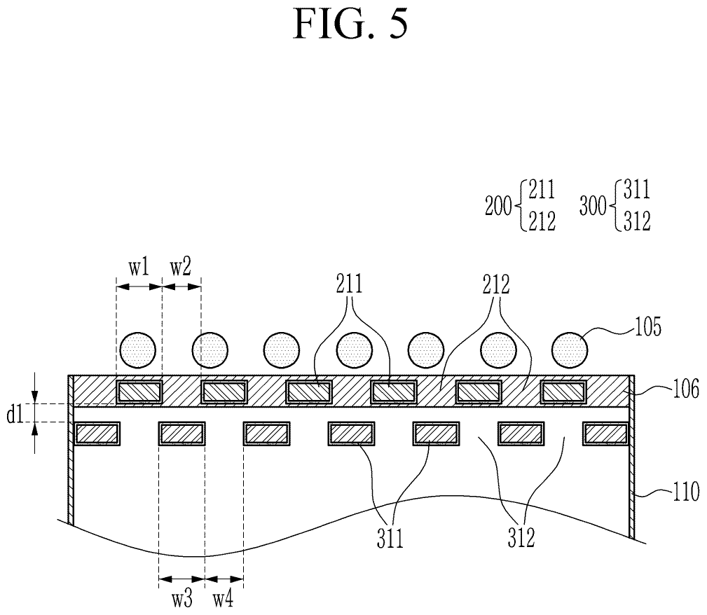

FIG. 4 shows structures of a first Faraday shield and a second Faraday shield in a plasma processing device according to an embodiment. FIG. 5 shows a variation of structures of a first Faraday shield and a second Faraday shield shown in FIG. 4.

Referring to FIG. 4 and FIG. 5, the first Faraday shield 200 may be integrally formed with the dielectric window 106. In detail, the first Faraday shield 200 may be integrally formed with the dielectric window 106 between the radio frequency antenna 105 and the chamber 110.

According to an embodiment, the first Faraday shield 200 may include the first portions 211 and the first openings 212. According to an embodiment, each of the first portions 211 may have a first width w1. The present disclosure has been described, to facilitate understanding and ease of description, such that each of the first portions 211 have the same first width w1. However, the present disclosure is not limited thereto, and each of the first portions 211 may have different widths.

According to an embodiment, each of the first openings 212 may have a second width w2. The present disclosure has been described, for better understanding and ease of description, such that each of the first openings 212 have the same second width w2. However, the present disclosure is not limited thereto, and each of the first openings 212 may have different widths.

According to an embodiment, the second Faraday shield 300 may be arranged to be exposed inside the chamber 110. The second Faraday shield 300 may be attached to the interior wall of the chamber 110 by a support member (not shown). According to an embodiment, the second Faraday shield 300 may be spaced apart from the first Faraday shield 200 in the perpendicular direction to the first Faraday shield 200 by a first distance d1. The second Faraday shield 300 and the first Faraday shield 200 may be arranged in parallel to each other with the first distance d1 therebetween. In detail, the second Faraday shield 300 may be spaced apart from the first Faraday shield 200 in the perpendicular direction to the first Faraday shield 200 by the first distance d1 in the plasma processing chamber 116.

According to an embodiment, the second Faraday shield 300 may include the second portions 311 and the second openings 312. According to an embodiment, each of the second portions 311 may have a third width w3. The present disclosure has been described, for better understanding and ease of description, such that each of the second portions 311 have the same third width w3. However, the present disclosure is not limited thereto, and each of the second portions 311 may have different widths.

According to an embodiment, each of the second openings 312 may have a fourth width w4. The present disclosure has been described, for better understanding and ease of description, such that the respective second openings 312 have the same fourth width w4. However, the present disclosure is not limited thereto, and the second openings 312 may have different widths.

According to an embodiment, when seen in the perpendicular direction to the upper surface of the chamber 110, the first Faraday shield 200 and the second Faraday shield 300 may be arranged such that the first openings 212 may stagger the second openings 312. That is, when seen in the perpendicular direction to the upper surface of the chamber 110, the first Faraday shield 200 and the second Faraday shield 300 may be arranged so that the first openings 212 may not overlap the second openings 312.

In detail, the first portions 211 of the first Faraday shield 200 may at least partly overlap the second openings 312 of the second Faraday shield 300 in the direction perpendicular to the first Faraday shield 200. The second portions 311 of the second Faraday shield 300 may at least partly overlap the first openings 212 of the first Faraday shield 200 in the perpendicular direction to the first Faraday shield 200. According to an embodiment, the first widths w1 of each of the first portions 211 may be equal to or greater than the fourth widths w4 of each of the second openings 312 of the second Faraday shield 300 so the entire region of the second openings 312 may be or may not be overlapped with the first portions 211 in the direction perpendicular to the first Faraday shield 200.

According to an embodiment, the third widths w3 of each of the second portions 311 may be equal to or greater than the second widths w2 of each of the first openings 212 of the first Faraday shield 200 so the entire region of the first openings 212 may be or may not be overlapped the second portions 311 in the direction perpendicular to the first Faraday shield 200.

Referring to FIG. 4, the first widths w1 of the first portions 211 may be greater than the fourth widths w4 of each of the second openings 312. As the first widths w1 of each of the first portions 211 are formed to have a greater width than the fourth widths w4 of each of the second openings 312, the first portions 211 may at least partly overlap the second openings 312 in the direction perpendicular to the first Faraday shield 200.

Referring to FIG. 5, the first widths w1 of each of the first portions 211 may be equal to the fourth widths w4 of each of the second openings 312. As the first widths w1 of each of the first portions 211 are formed to have the same width as the fourth widths w4 of each of the second openings 312, the first portions 211 may not overlap the second openings 312 in the direction perpendicular to the first Faraday shield 200.

Referring to FIG. 4, the third widths w3 of each of the second portions 311 may be greater than the second widths w2 of the first openings 212. As the third widths w3 of each of the second portions 311 are formed to have a greater width than the second widths w2 of each of the first openings 212, the second portions 311 may at least partly overlap the first openings 212 in the direction perpendicular to the first Faraday shield 200.

Referring to FIG. 5, the third widths w3 of each of the second portions 311 may be equal to the second widths w2 of each of the first openings 212. As the third widths w3 of each of the second portions 311 are formed to have the same width as the second widths w2 of each of the first openings 212, the second portions 311 may not overlap the first openings 212 in the direction perpendicular to the first Faraday shield 200.

As described above, by arranging the first openings 212 of the first Faraday shield 200 and the second openings 312 of the second Faraday shield 300 in a staggered manner, it is possible to prevent the weakening of the induced electric field caused by the formation of the eddy current.

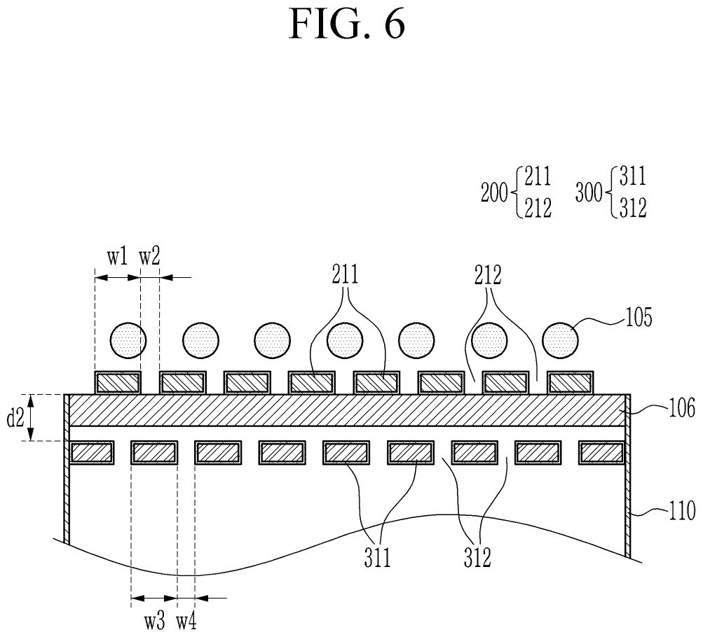

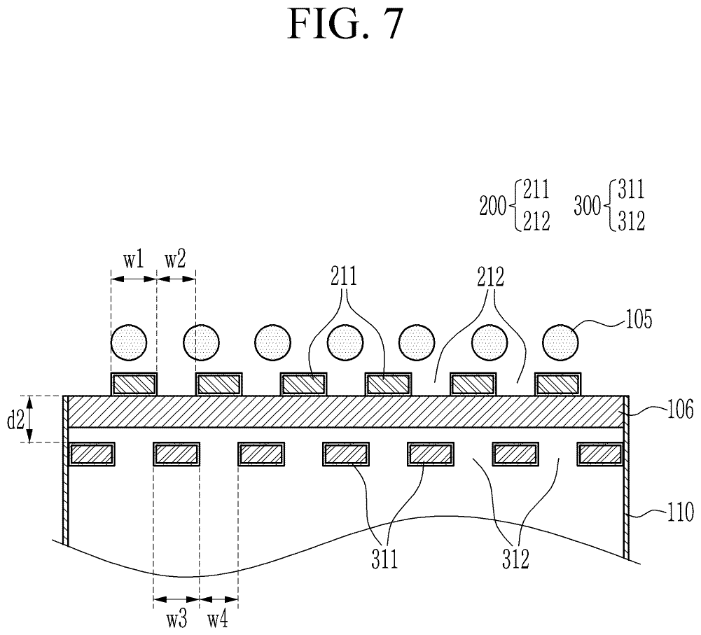

FIG. 6 shows structures of a first Faraday shield and a second Faraday shield in a plasma processing device according to an embodiment. FIG. 7 shows a variation of structures of a first Faraday shield and a second Faraday shield shown in FIG. 6.

Referring to FIG. 6 and FIG. 7, the first Faraday shield 200 may be arranged between the radio frequency antenna 105 and the dielectric window 106. For example, the first Faraday shield 200 may contact the upper surface of the dielectric window 106 between the radio frequency antenna 105 and the dielectric window 106.

According to an embodiment, the first Faraday shield 200 may include the first portions 211 and the first openings 212. According to an embodiment, each of the first portions 211 may have a first width w1. The present disclosure has been described, for better understanding and ease of description, such that each of the first portions 211 have the same first width w1. However, the present disclosure is not limited thereto, and each of the first portions 211 may have different widths.

According to an embodiment, each of the first openings 212 may have a second width w2. The present disclosure has been described, for better understanding and ease of description, such that each of the first openings 212 have the same second width w2. However, the present disclosure is not limited thereto, and each of the first openings 212 may have different widths.

According to an embodiment, the second Faraday shield 300 may be exposed inside the chamber 110. The second Faraday shield 300 may be attached to the interior wall of the chamber 110 by a support member (not shown). According to an embodiment, the second Faraday shield 300 may be spaced from the first Faraday shield 200 by a second distance d2 in the direction perpendicular to the first Faraday shield 200. According to an embodiment, the second distance d2 may be greater than the first distance (e.g., the first distance d1 shown in FIG. 4 or FIG. 5) which is a distance between the first Faraday shield 200 and the second Faraday shield 300 when the first Faraday shield 200 and the dielectric window 106 are integrally formed.

According to an embodiment, the second Faraday shield 300 may include the second portions 311 and the second openings 312. According to an embodiment, each of the second portions 311 may have a third width w3. The present disclosure has been described, for better understanding and ease of description, such that each of the second portions 311 have the same third width w3. However, the present disclosure is not limited thereto, and each of the second portions 311 may have different widths.

According to an embodiment, each of the second openings 312 may have a fourth width w4. The present disclosure has been described, for better understanding and ease of description, such that each of the second openings 312 have the same fourth width w4. However, the present disclosure is not limited thereto, and each of the second openings 312 may have different widths.

According to an embodiment, when seen in the direction perpendicular to the upper surface of the chamber 110, the first Faraday shield 200 and the second Faraday shield 300 may be arranged such that the first openings 212 stagger the second openings 312. That is, when seen in the direction perpendicular to the upper surface of the chamber 110, the first Faraday shield 200 and the second Faraday shield 300 may be arranged so that the first openings 212 do not overlap the second openings 312.

In detail, the first portions 211 of the first Faraday shield 200 may at least partly overlap the second openings 312 of the second Faraday shield 300 in the direction perpendicular to the first Faraday shield 200. The second portions 311 of the second Faraday shield 300 may at least partly overlap the first openings 212 of the first Faraday shield 200 in the direction perpendicular to the first Faraday shield 200.

According to an embodiment, the first widths w1 of each of the first portions 211 of the first Faraday shield 200 may be equal to or greater than the fourth widths w4 of each of the second openings 312 of the second Faraday shield 300. Referring to FIG. 6, the first widths w1 of each of the first portions 211 may be greater than the fourth widths w4 of each of the second openings 312. Referring to FIG. 7, the first widths w1 of each of the first portions 211 may be equal to the fourth widths w4 of the second openings 312.

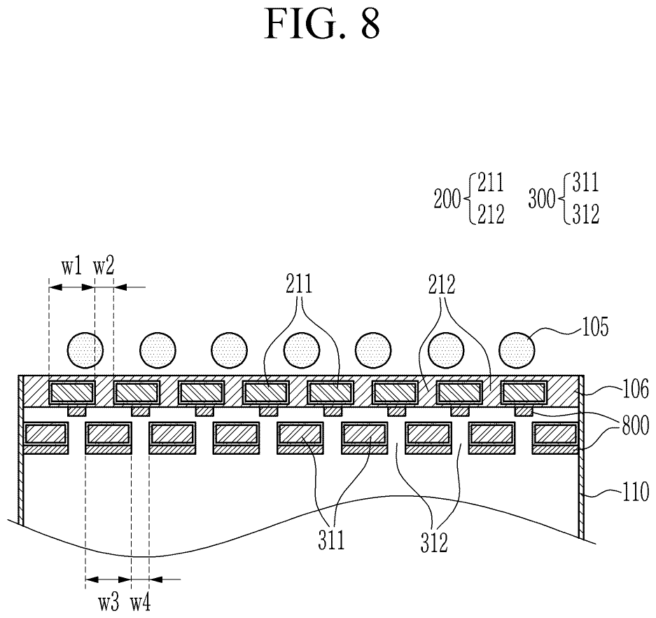

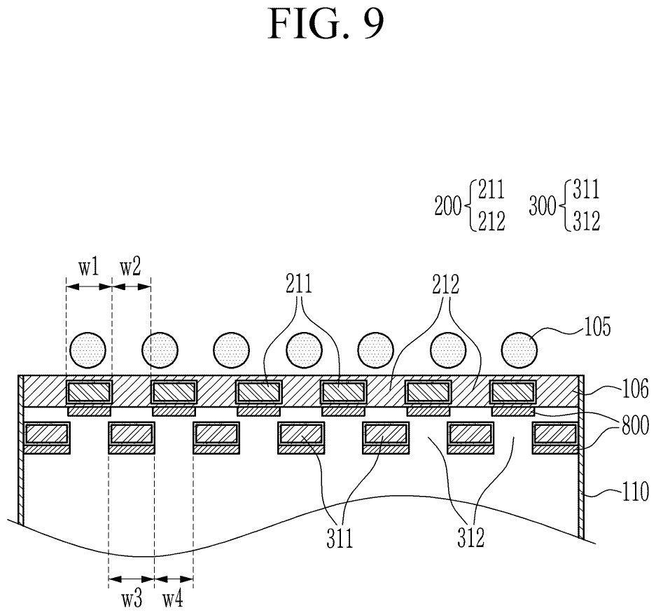

FIG. 8 shows an attachment of by-products to a first Faraday shield and a second Faraday shield in a plasma processing device according to an embodiment. FIG. 9 shows a variation of the attachment of by-products to a first Faraday shield and a second Faraday shield shown in FIG. 8.

Referring to FIG. 8 and FIG. 9, as an etching process on an etching object progresses, the by-product 800 from the etching object may be attached to the chamber 110. For example, the etching object may include a copper layer included in a substrate (e.g., substrate 114 of FIG. 1). In detail, the etching object may correspond to the copper layer which is etched on the substrate 114 to form a circuit or a component including wires and electrodes. However, the etching object may not be limited to the copper layer and may include other material layers depending on various embodiments.

As shown in FIG. 8 and FIG. 9, the etching process may proceed in a plasma processing device (e.g., the plasma processing device 100 in FIG. 1) where first Faraday shield 200 may be integrally formed with the dielectric window 106, and the second Faraday shield 300 may be arranged to be exposed inside the chamber 110. According to an embodiment, as the etching process progresses, the by-product 800 from the etching object may be attached to the inside of the chamber 110. For example, the by-product 800 from the etching object may be attached to an internal surface of an upper portion of the chamber 110. For example, when the dielectric window 106 forms the upper portion of the chamber 110, the by-product 800 from the etching object may be attached to the dielectric window 106.

When seen in the direction perpendicular to the upper surface of the chamber 110, the second Faraday shield 300 may be arranged inside the chamber 110 and the first openings 212 and the second openings 312 are alternately arranged in a staggered manner, such that the by-product 800 may be partly attached to the upper surface of the chamber 11 by a shadow effect. That is, the by-product 800 may not cover the entire upper surface of the chamber 110.

According to an embodiment, when the dielectric window 106 forms the upper portion of the chamber 110, the by-product 800 may be partly attached to the dielectric window 106.

According to an embodiment, the width of the by-product 800 may correspond to the fourth width w4 of the second opening 312. That is, the width of the by-product 800 attached to the upper surface of the chamber 110 311 may correspond to the fourth width w4 of the second opening 312.

Referring to FIG. 8, when the first widths w1 of each of the first portions 211 are greater than the fourth widths w4 of each of the second openings 312, the width of the by-product 800 may be less than the first width w1.

Referring to FIG. 9, when the first widths w1 of each of the first portions 211 are equal to the fourth widths w4 of each of the second openings 312, the width of the by-product 800 may be equal to or close to the first width w1. That is, the by-product 800 may have a shape similar to the first portion 211, thereby efficiently blocking the eddy current.

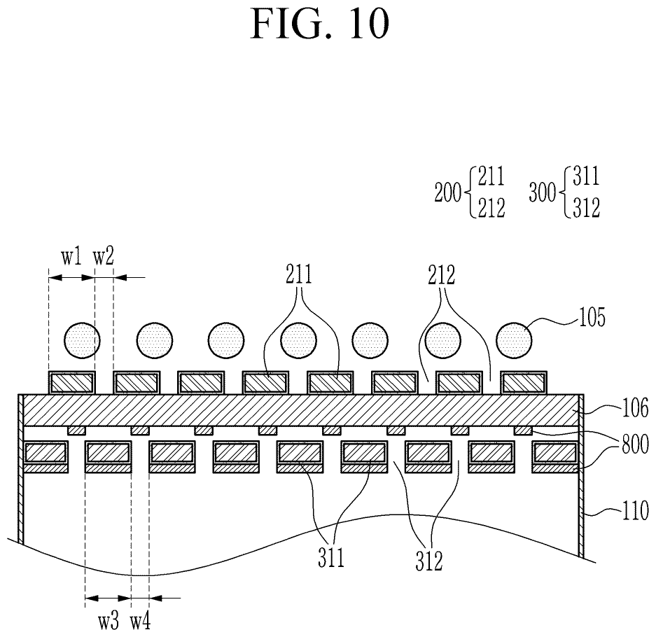

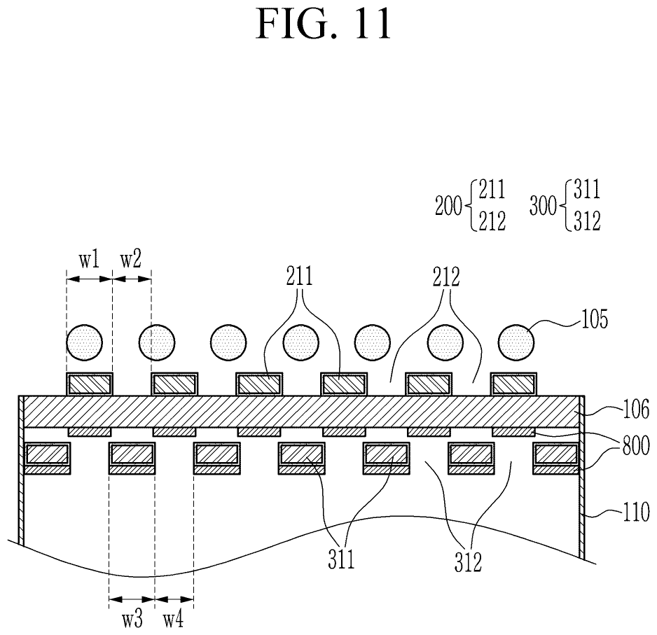

FIG. 10 shows attachment of by-products to a first Faraday shield and a second Faraday shield in a plasma processing device according to an embodiment. FIG. 11 shows a variation of attachment of by-products to a first Faraday shield and a second Faraday shield shown in FIG. 10.

The description of by-products according to an embodiment shown in FIG. 10 and FIG. 11 is substantially similar to the description with reference to FIG. 8 and FIG. 9. Therefore, the repeated explanation may be summarized or omitted. In the present embodiment, the position of the first Faraday shield 200 may be partly different from the above-described embodiment, which will now be described below.

Referring to FIG. 10 and FIG. 11, the etching process may proceed in a plasma processing device (e.g., the plasma processing device 100 in FIG. 1) where the first Faraday shield 200 may be disposed between the radio frequency antenna 105 and the dielectric window 106, and the second Faraday shield 300 may be arranged to be exposed inside the chamber 110.

According to an embodiment, as the etching process progresses, the by-product 800 from the etching object may be attached to the inside of the chamber 110. When seen in the direction perpendicular to the upper surface of the chamber 110, the second Faraday shield 300 may be arranged inside the chamber 110 and the first openings 212 and the second openings 312 are alternately arranged in a staggered manner, such that the by-product 800 may be partially attached to the top surface of the chamber 110.

That is, the by-product 800 from the etching object may not cover the entire upper surface of the chamber 110.

According to an embodiment, when the dielectric window 106 forms the upper portion of the chamber 110, the by-product 800 may be partly attached to the dielectric window 106.

According to an embodiment, the width of the by-product 800 may correspond to the fourth width w4 of the second opening 312. That is, the width of the by-product 800 attached to the upper surface of the chamber 110 may correspond to the fourth width w4 of the second opening 312.

Referring to FIG. 10, when the first widths w1 of each of the first portions 211 are greater than the fourth widths w4 of each of the second openings 312, the width of the by-product 800 may be less than the first width w1.

Referring to FIG. 11, when the first widths w1 of each of the first portions 211 are equal to the fourth widths w4 of each of the second openings 312, the width of the by-product 800 may be equal to or close to the first width w1. That is, the by-product 800 may have a shape similar to the first portion 211, thereby efficiently blocking the eddy current.

As described above, by arranging the first Faraday shield 200 and the second Faraday shield 300 to place the first openings 212 and the second openings 312 in a staggered manner, the eddy current may be prevented as the by-product 800 has the similar shape to the first Faraday shield 200.

Further, since the resistance of the by-product 800 may be higher than that of the first Faraday shield 200, the by product 800 may have less or no effect on the power transmission characteristics of the first Faraday shield 200. Hence, this may prevent the reduction of power transfer efficiency into the plasma treatment space due to the eddy current.

While the present disclosure has been described above, it is to be understood that the present disclosure is not limited to the disclosed embodiments. On the contrary, it is intended to cover various modifications and equivalent arrangements included within the spirit and scope of the appended claims.

What is claimed is:

1. A plasma processing device comprising:
a chamber in which plasma process is performed;
a radio frequency antenna connected to a radio frequency power source;
a dielectric window disposed between the radio frequency antenna and the chamber;
a first Faraday shield disposed on the chamber and including first portions and first openings; and
a second Faraday shield disposed inside the chamber and including second portions and second openings,
wherein the first openings and the second openings are alternately arranged in a staggered manner along a perpendicular direction to an upper surface of the chamber.

2. The plasma processing device of claim 1, wherein
the first portions radially extend outward from a center of the first Faraday shield and are connected to a first edge, and
the second portions radially extend outward from a center of the second Faraday shield and are connected to a second edge.

3. The plasma processing device of claim 2, wherein
the first portions and the first openings are alternately arranged in a plan view, and
the second portions and the second openings are alternately arranged in the plan view.

4. The plasma processing device of claim 1, wherein
the first portions at least partly overlap the second openings in the perpendicular direction, and
the second portions at least partly overlap the first openings in the perpendicular direction.

5. The plasma processing device of claim 1, wherein
the first Faraday shield is spaced apart from the second Faraday shield in the perpendicular direction.

6. The plasma processing device of claim 1, wherein
the first Faraday shield is separated from the chamber by an insulating layer or is coated with an insulating film.

7. The plasma processing device of claim 1, wherein
the first Faraday shield is integrally formed with the dielectric window.

8. The plasma processing device of claim 1, wherein
the first Faraday shield is disposed between the radio frequency antenna and the dielectric window.

9. The plasma processing device of claim 1, further comprising
a support member disposed inside the chamber,
wherein the support member attaches the second Faraday shield to the upper surface of the chamber or an interior wall of the chamber.

10. The plasma processing device of claim 1, wherein
the first Faraday shield and the second Faraday shield are made of a non-magnetic metal.

11. The plasma processing device of claim 1, wherein
a surface of the second Faraday shield is coated with at least one of Al₂O₃ and Y₂O₃.

12. The plasma processing device of claim 1, wherein
the first Faraday shield and the second Faraday shield have quadrangular shapes.

13. A plasma processing system comprising:
a plasma processing device including a chamber in which plasma processing is performed, a radio frequency antenna connected to a radio frequency power source, a dielectric window disposed between the radio frequency antenna and the chamber, a first Faraday shield disposed on the chamber and including first portions and first openings, and a second Faraday shield disposed inside the chamber and including second portions and second openings;
a power supply disposed outside the chamber and connected to the second Faraday shield; and
a cooling fluid supplying portion connected to a cooling path of the second Faraday shield,
wherein the first openings and the second openings are alternately arranged in a staggered manner.

14. The plasma processing system of claim 13, wherein
the power supply supplies at least one of a DC voltage, an AC current, and an RF electric power to the second Faraday shield.

15. The plasma processing system of claim 13, wherein
the cooling fluid supplying portion supplies a liquefied or gaseous fluid to an inlet of the cooling path to adjust a temperature of the second Faraday shield.

16. The plasma processing system of claim 13, wherein
the first Faraday shield includes first portions radially extending outward from a center and connected to a first edge, and
the second Faraday shield includes second portions radially extending outward from a center and connected to a second edge.

17. The plasma processing system of claim 16, wherein
the first portions and the first openings are alternately arranged in a plan view, and
the second portions and the second openings are alternately arranged in the plan view.

18. The plasma processing system of claim 13, wherein
the first portions at least partly overlap the second openings in a perpendicular direction to an upper surface of the chamber, and
the second portions at least partly overlap the first openings in the perpendicular direction.

19. The plasma processing system of claim 13, wherein
the first Faraday shield is integrally formed with the dielectric window.

20. The plasma processing system of claim 13, wherein
the first Faraday shield is disposed between the radio frequency antenna and the dielectric window.
